(19) United States
(12) Patent Application Publication
(10) Pub. No.: US 2026/0239803 A1
(43) Pub. Date: Aug. 13, 2026

(54) FLEXIBLE LEAD FRAME

(71) Applicant: CreeLED, Inc., Durham, NC (US)

(72) Inventors: Michael Check, Holly Springs, NC (US); David Suich, Durham, NC (US); Joseph G. Sokol, Durham, NC (US); Colin Blakely, Raleigh, NC (US)

(21) Appl. No.: 19/049,692

(22) Filed: Feb. 10, 2025

(51) Int. Cl. H10H 29/85; H10H 29/24

(52) U.S. Cl. CPC H10H 29/857; H10H 29/24

(57) ABSTRACT

Light-emitting diode (LED) devices, and more particularly, flexible lead frames in LED packages are disclosed. Exemplary lead frames are provided that are flexible to dampen thermal expansion or contraction of the lead frame on which the LED device is mounted relative to the thermal expansion or contraction of the LED device. Relief elements in the lead frame can reduce the force applied to the LED device when the LED package undergoes temperature changes, and thereby lowering the likelihood of the LED device cracking or suffering other damage that impacts the reliability and operation of the LED device in the LED package.

### FIELD OF THE DISCLOSURE

The present disclosure relates to light-emitting diode devices, and more particularly to flexible lead frames in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs continue to enable a variety of new LED display and general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices and more particularly to flexible lead frames in LED packages. Exemplary lead frames are provided that are flexible to dampen thermal expansion or contraction of the lead frame on which the LED device is mounted relative to the thermal expansion or contraction of the LED device. Relief elements in the lead frame can reduce the force applied to the LED device when the LED package undergoes temperature changes, and thereby lowering the likelihood of the LED device cracking or suffering other damage that impacts the reliability and operation of the LED device in the LED package.

In one aspect, a LED package includes a lead frame structure comprising two or more leads, wherein one or more of the leads comprise one or more relief elements, wherein the one or more relief elements enable movement of the one or more leads relative to a remainder of the lead frame structure and an LED chip positioned on the lead frame structure, wherein the LED chip is attached to the two or more leads. In an embodiment the one or more relief elements of the one or more leads are configured to dampen thermal expansion or contraction of the lead frame structure. In an embodiment, the two or more leads each comprise one or more relief elements. In an embodiment, the one or more relief elements are one or more cutouts. In an embodiment, the one or more leads comprise a plurality of relief elements arranged in a predefined pattern. In an embodiment, the one or more leads move relative to the remainder of the lead frame structure via elastic deformation. In an embodiment, the one or more leads move relative to the remainder of the lead frame structure via plastic deformation. In an embodiment, there are a plurality of LED chips mounted on the lead frame structure.

In another aspect, an LED package includes a housing, a lead frame structure, mounted in the housing, wherein the lead frame structure comprises two or more leads, wherein one or more of the leads comprise one or more relief elements, wherein the one or more relief elements enable movement of the one or more leads relative to the housing, and an LED chip positioned on the lead frame structure, wherein the LED chip is attached to the two or more leads. In an embodiment the one or more relief elements of the one or more leads are configured to dampen thermal expansion or contraction of the lead frame structure. In an embodiment, the two or more leads each comprise one or more relief elements. In an embodiment, the one or more relief elements are one or more cutouts. In an embodiment, the one or more leads comprise a plurality of relief elements arranged in a predefined pattern. In an embodiment, the one or more leads move relative to the remainder of the lead frame structure via elastic deformation. In an embodiment, the one or more leads move relative to the remainder of the lead frame structure via plastic deformation. In an embodiment, there are a plurality of LED chips mounted on the lead frame structure. In an embodiment the LED package further includes an encapsulant, wherein the housing forms a recess in which the LED chip is positioned, and the encapsulant is within the recess and at least partially fills openings formed by the one or more relief elements

In another aspect, a lighting device includes a board and a LED package mounted on the board. The LED package includes a housing, a lead frame structure, mounted in the housing, wherein the lead frame structure comprises two or more leads, wherein one or more of the leads comprise one or more relief elements, wherein the one or more relief elements enable movement of the one or more leads relative to the housing, and an LED chip positioned on the lead frame structure, wherein the LED chip is attached to the two or more leads. In an embodiment, the one or more relief elements of the one or more leads are configured to dampen thermal expansion or contraction of the lead frame structure. In an embodiment, the two or more leads each comprise one or more relief elements. In an embodiment, the one or more relief elements are one or more cutouts.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) package with a flexible lead frame according to principles of the present disclosure.

FIG. 2 is a cross-sectional view of another light-emitting diode (LED) package with a flexible lead frame according to principles of the present disclosure.

FIG. 3 is a top-down view of the LED package of FIG. 2 according to principles of the present disclosure.

FIG. 4 is a top-down view of another LED package similar to FIG. 3, but with different shaped relief elements according to principles of the present disclosure.

FIGS. 5A-H display a variety of types and shapes of relief elements for the lead frame according to principles of the present disclosure.

FIG. 6 displays a flexible lead frame structure in a sheet that can support multiple LED chips according to principles of the present disclosure.

FIG. 7 is a schematic diagram of a portion of an LED device, such as a display screen including a large number of LED packages according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Submounts and lead frames are two common ways to attach and make light-emitting diode (LED) components, and typically, the temperatures at which the LED chips are attached to a lead frame are higher than standby or operational temperatures. Due to differences in the thermal coefficient of expansion of the materials in the lead frame or submount and the materials in the LED chip, the differences in contraction or expansion due to temperature changes can cause the lead frame structure on which the LED chip is mounted to apply force to the LED chip, thereby causing the die of the LED chip to crack, or leading to poor die attach or voiding, and causing other reliability concerns. Some attempts to counter these problems have used different metals or materials to bond the LED chip to the lead frame have included bismuth instead of the standard SAC (Tin, Silver, Copper) bond, which uses lower process temperatures during attachment than SAC. SAC is the better bond metal, however, and requires a higher temperature, leading to a higher rate of damaged LED chips once the LED package cools. To reduce this, and dampen the forces applied to the LED device, the flexible lead frames with relief elements are provided as described in the present disclosure.

The present disclosure relates to light-emitting diode (LED) devices and more particularly to flexible lead frames in LED packages. Exemplary lead frames are provided that are flexible to dampen thermal expansion or contraction of the lead frame on which the LED device is mounted relative to the thermal expansion or contraction of the LED device. Relief elements in the lead frame can reduce the force applied to the LED device when the LED package undergoes temperature changes, and thereby lowering the likelihood of the LED device cracking or suffering other damage that impacts the reliability and operation of the LED device in the LED package.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements.

The active LED structure can be fabricated from different material systems, with some material systems being Group III nitride-based material systems. Group III nitrides refer to semiconductor compounds formed between nitrogen (N) and elements in Group III of the periodic table, usually aluminum (Al), gallium (Ga), and/or indium (In) in the form of binary, ternary, and/or quaternary compounds. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to single-chip LED packages and multiple-chip LED packages where multiple LED chips are arranged within a common recess and sometimes beneath a common lens of an LED package. For multiple-chip examples, LED packages may include a red-emitting LED chip, a green-emitting LED chip, and a blue-emitting LED chip such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG: Ce), green (e.g., LuAg:Ce), and red (e.g., Cai-x-ySrxEuyAlSiN3) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a support structure of an LED package such that the anode and cathode connections are on a face of the LED chip that is opposite the support structure. In this configuration, wire bonds may be used to provide electrical connections with the anode and cathode connections. In other embodiments, a lateral geometry LED chip may be flip-chip mounted on a surface of a support structure of an LED package such that the anode and cathode connections are on a face of the active LED structure that is adjacent to the support structure. In this configuration, electrical traces or portions of a lead frame may be provided with the support structure for providing electrical connections to the anode and cathode connections of the LED chip. In a flip-chip configuration, the active LED structure is configured between the substrate of the LED chip and the support structure for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure. Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. Encapsulant materials may also form lenses that direct light in desired emission directions and/or patterns. In certain embodiments, one or more lumiphoric materials, such as phosphor particles, may be integrated or otherwise embedded within the encapsulant material.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO2), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

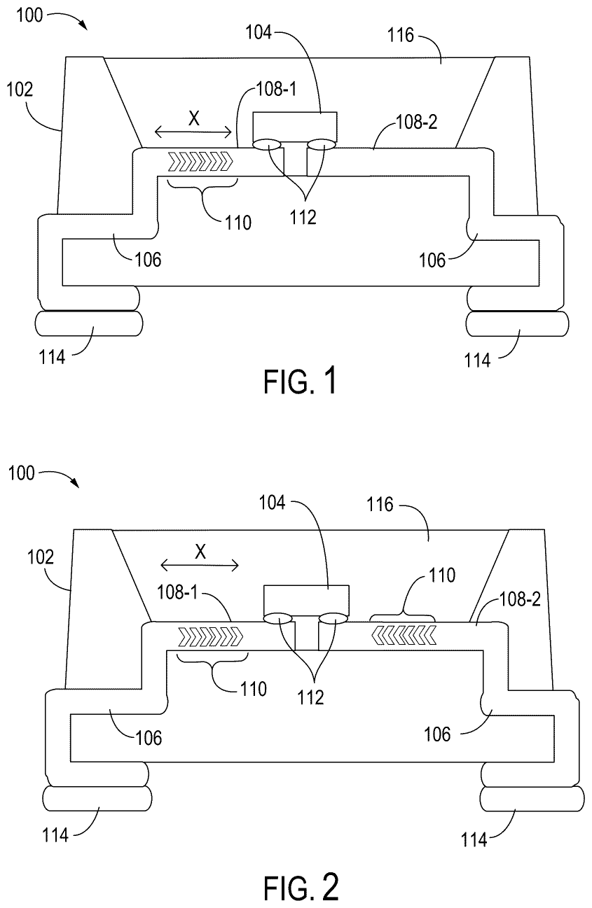

FIG. 1 is a cross-sectional view of a light-emitting diode (LED) package with a flexible lead frame according to principles of the present disclosure.

FIG. 1 includes an LED package 100 that includes a housing 102 with a lead frame structure 106 mounted therein. The lead frame structure 106 can have an LED chip 104 mounted thereon with electrodes 112 that are soldered and electrically coupled to the leads 108-1 and 108-2 of the lead frame structure 106. The lead 108-1 and 108-2 extend through the housing 102 to contact the electrodes 114 (e.g., traces on a printed circuit board). In an embodiment, after the LED package 100 is fabricated, the LED package 100 may be subsequently bonded to another surface, such as within an LED display or other lighting device. In this manner, portions of the leads 108-1 and 108-2 that extend along and outside a bottom of the housing 102 are bonded with additional bonding materials.

A lead (e.g., 108-1) of the lead frame structure 106 can include relief elements 110 that are formed in the lead 108-1. These relief elements can be cutouts that are mechanically formed via punchouts, or via etching, where the etching could include chemical etching (reactive ion etching, inductively coupled plasma etching), laser etching, sandblasting, or CO₂ blasting. These relief elements 110 allow for increased contraction and expansion of the lead 108-1 along the X direction indicated in FIG. 1 and also allow flexing or bending of the lead 108-1 to accommodate stresses that could arise during the die attach procedure of attaching LED chip 104 to the lead frame structure 106 or during thermal cycling.

In an embodiment, an encapsulant 116 is provided to fill in recess formed by the housing 102 and around the LED chip 104, and the encapsulant is within the recess and at least partially fills openings formed by the one or more relief elements 110. The encapsulant could be silicone or silicone embedded with lumiphoric material. In an embodiment, the encapsulant material would permit flexing of the leads better than the material of the rigid housing.

For example, during the die attach process, the temperature at which the LED chip 104 is mounted to the lead frame structure 106 can be 250 degrees Celsius, which is considerably higher than room temperature or even the operational temperature of around 100-130 degrees Celsius. When the LED package 100 cools after the LED chip 104 is mounted on the lead frame structure 106, the differential contraction due to the different coefficients of thermal expansion of the LED chip 104 and the lead frame structure may cause the leads 108-1 and 108-2 to apply a tensile force or compressive force to the LED chip 104, thus risking damage to the LED chip 104, or cracking of the bonding between the LED chip 104 and the lead frame structure 106. The relief elements 110 in lead 108-1 can enable the lead 108-1 to move relative to the rest of the lead frame structure 106 and thus dampen the tensile or compressive force applied to the LED chip 104.

The relief elements 110 reduce the amount of material in the cross section of the lead 108-1, which increase the amount of deformation the lead 108-1 is able to undergo relative to the lead frame structure 106 for a given force, where the deformation could be either elastic or plastic.

FIG. 2 is a cross-sectional view of another light-emitting diode (LED) package with a flexible lead frame according to principles of the present disclosure.

FIG. 2 is similar to FIG. 1 except that the relief elements 110 can be formed in both leads 108-1 to 108-2, instead of just one of the leads 108-1 as in FIG. 1. Having relief elements 110 in both leads 108-1 and 108-2 can increase the amount of flex that the lead frame structure has and can dampen increased thermal contraction or expansion relative to the embodiment in FIG. 1.

It is to be appreciated that while FIG. 1 and FIG. 2 show a single LED chip mounted on the lead frame structure, in other embodiments, multiple LED chips, of the same or different colors, can be mounted on the lead frame structure, with the lead frame structure 106 providing a three-dimensional shape around a plurality of LED chips.

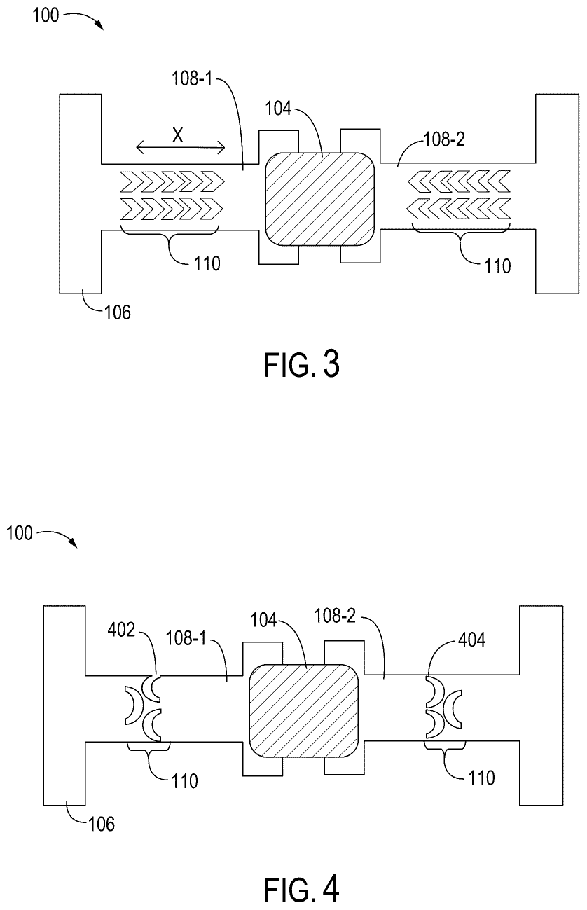

FIG. 3 is a top-down view of the LED package of FIG. 2 according to principles of the present disclosure.

In FIG. 3, the relief elements 110 are on both leads 108-1 and 108-2, and in the image shown appear in two rows on each lead. In other embodiments, the relief elements 110 could be a single row, or could be in multiple rows, with the number of rows being based on the amount of deformation required, the size of the cutouts of the relief elements 110, and the width of the leads 108-1 and 108-2.

FIG. 4 is a top-down view of another LED package similar to FIG. 3, but with different shaped relief elements according to principles of the present disclosure. The relief elements 110 in FIG. 4 are crescent shaped cuts as opposed to the chevrons in FIG. 3. The shape of the cutout can affect the type and amount of deformation desired, where the crescent shaped cuts of FIG. 4 may allow more rotational deformation (rotational around the center of the lead 108-1 or 108-2) while the chevrons of FIG. 3 allow more deformation in the in the X direction shown. In an embodiment, the cutouts of the relief elements 110 may be made across the edges of the lead frame as shown at 402 in FIG. 4, or can be entirely within lead frame as shown at 404 in FIG. 4.

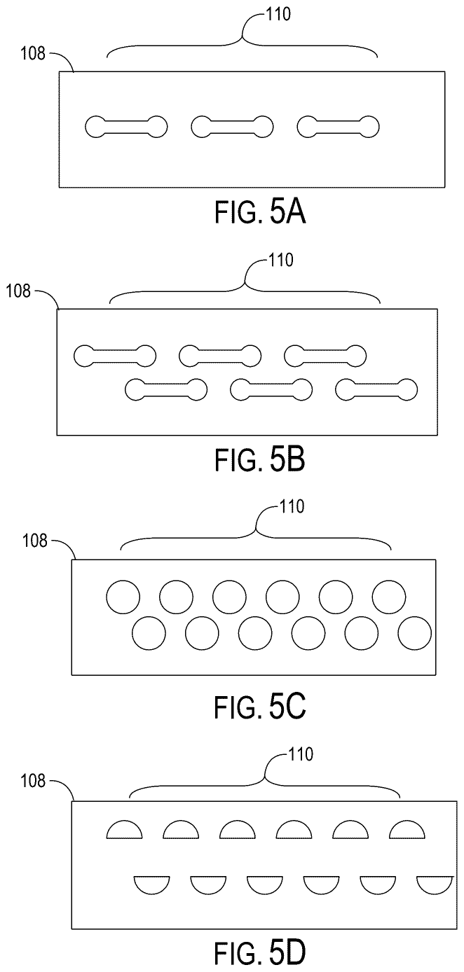

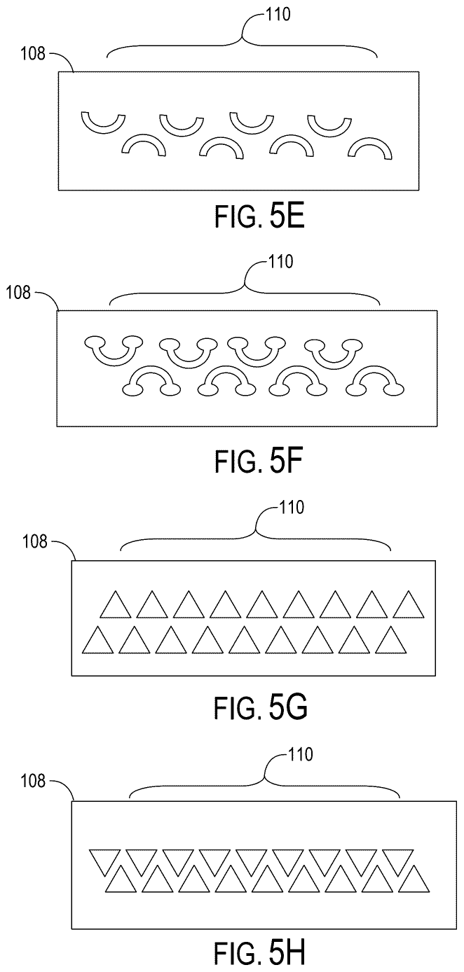

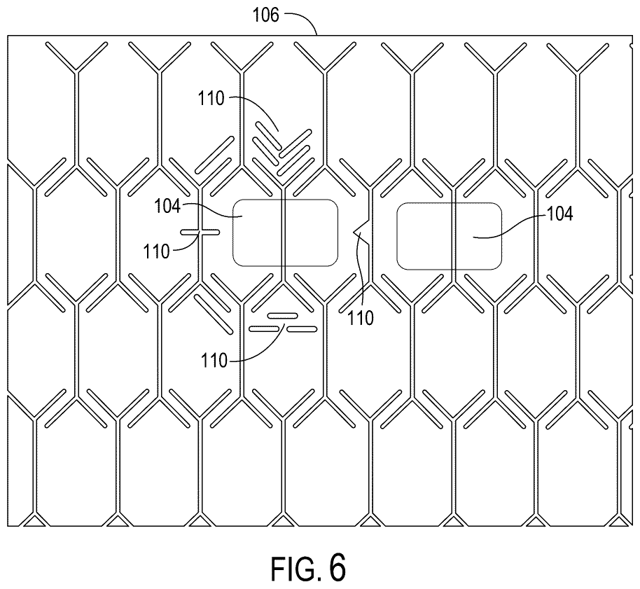

FIGS. 5A-H display a variety of types and shapes and patterns of relief elements 110 for the lead 108 according to principles of the present disclosure. For example, in FIG. 5A, the dumbbell shaped cutouts can be in a single row, whereas in FIG. 5B, the dumbbell shaped cutouts can be in two rows. In other embodiments, other numbers of rows are possible.

In FIG. 5C, the relief elements 110 can be in the form of an array of circular cutouts, whereas in FIG. 5D the relief elements 110 are semi-circle cutouts.

In FIG. 5E, the relief elements 110 can be crescent shaped cutouts similar to FIG. 4, except with the cutouts oriented 90 degrees to the embodiment in FIG. 4.

In FIG. 5F, there can be curved dumbbell shaped cutouts for relief elements 110.

In FIG. 5G, the relief elements 110 can be in the form of triangular cutouts, each oriented the same way, whereas in FIG. 5H, the relief elements 110 are arranged with different orientations for each row.

It is to be appreciated that the patterns and shapes in FIG. 5 are just a small sampling of the types of shapes and patterns possible in other embodiments.

FIG. 6 displays a flexible lead frame structure in a sheet that can support multiple LED chips according to principles of the present disclosure.

The lead frame structure 106 in FIG. 6 can be a flexible sheet on which a plurality of LED chips 104 can be placed. The flexible sheet lead frame 106 can include one or more sets of relief elements 110 in various patterns, configurations, and/or locations on the flexible sheet lead frame 106.

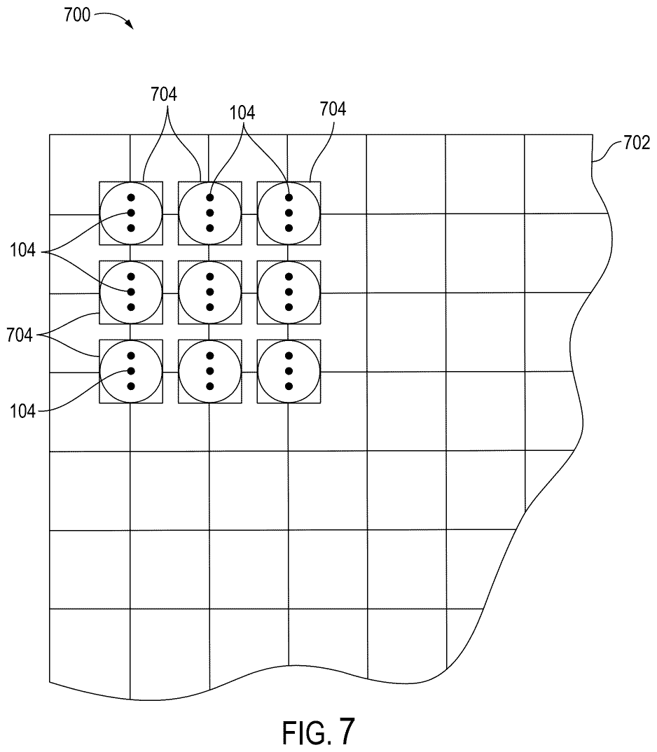

FIG. 7 is a schematic diagram of a portion of an LED device, such as a display screen including a large number of LED packages according to principles of the present disclosure.

FIG. 7 is a schematic diagram of a portion of an LED device 700, such as a display screen, for example, an indoor and/or outdoor screen comprising, in general terms, a display panel including a driver printed circuit board (PCB) 702 carrying a large number of surface-mount devices (SMDs) 704 arranged in rows and columns, each SMD 704 defining a pixel. Additionally, each SMD 704 may represent a multiple chip embodiment of different colors, such as red-green-blue, for forming an LED pixel. The SMDs 704 are electrically connected to traces or pads on the PCB 702 to respond to appropriate electrical signal processing and driver circuitry (not shown). While FIG. 7 depicts the LED chips 104 in a linear arrangement within each LED package for the SMDs 704, in other embodiments, the LED chips 104 may be arranged in different configurations. During formation of the LED device 700, the lead frame structure 106 can have the relief elements 110 formed in the lead frame structure 106 to enable the lead frame structure to flex and thus dampen the forces applied to the LED chip(s) 104. In this regard, the reliability of the LED devices can be improved by preventing cracks in the LED chips and damaged bonds.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light emitting diode (LED) package, comprising:
a lead frame structure comprising two or more leads, wherein one or more of the leads comprise one or more relief elements, wherein the one or more relief elements enable movement of the one or more leads relative to a remainder of the lead frame structure; and
an LED chip positioned on the lead frame structure, wherein the LED chip is attached to the two or more leads.

2. The LED package of claim 1, wherein the one or more relief elements of the one or more leads are configured to dampen thermal expansion or contraction of the lead frame structure.

3. The LED package of claim 1, wherein the two or more leads each comprise one or more relief elements.

4. The LED package of claim 1, wherein the one or more relief elements are one or more cutouts.

5. The LED package of claim 1, wherein the one or more leads comprise a plurality of relief elements arranged in a predefined pattern.

6. The LED package of claim 1, wherein the one or more leads move relative to the remainder of the lead frame structure via elastic deformation.

7. The LED package of claim 1, wherein the one or more leads move relative to the remainder of the lead frame structure via plastic deformation.

8. The LED package of claim 1, wherein there are a plurality of LED chips mounted on the lead frame structure.

9. A light emitting diode (LED) package, comprising
a housing,
a lead frame structure at least partially within in the housing, wherein the lead frame structure comprises two or more leads, wherein one or more of the leads comprise one or more relief elements, wherein the one or more relief elements enable movement of the one or more leads relative to the housing; and
an LED chip positioned on the lead frame structure, wherein the LED chip is attached to the two or more leads.

10. The LED package of claim 9, wherein the one or more relief elements of the one or more leads are configured to dampen thermal expansion or contraction of the lead frame structure.

11. The LED package of claim 9, wherein the two or more leads each comprise one or more relief elements.

12. The LED package of claim 9, wherein the one or more relief elements are one or more cutouts.

13. The LED package of claim 9, wherein the one or more leads comprise a plurality of relief elements arranged in a predefined pattern.

14. The LED package of claim 9, wherein the one or more leads move relative to the remainder of the lead frame structure via elastic deformation.

15. The LED package of claim 9, wherein the one or more leads move relative to the remainder of the lead frame structure via plastic deformation.

16. The LED package of claim 9, wherein there are a plurality of LED chips mounted on the lead frame structure.

17. The LED package of claim 9, further comprising an encapsulant, wherein the housing forms a recess in which the LED chip is positioned, and the encapsulant is within the recess and at least partially fills openings formed by the one or more relief elements.

18. A lighting device comprising:
a board; and
a light-emitting diode (LED) package mounted on the board, the LED package comprising:
a housing,
a lead frame structure, mounted in the housing, wherein the lead frame structure comprises two or more leads, wherein one or more of the leads comprise one or more relief elements, wherein the one or more relief elements enable movement of the one or more leads relative to the housing; and
an LED chip positioned on the lead frame structure, wherein the LED chip is attached to the two or more leads.

19. The lighting device of claim 18, wherein the one or more relief elements of the one or more leads are configured to dampen thermal expansion or contraction of the lead frame structure.

20. The lighting device of claim 18, wherein the two or more leads each comprise one or more relief elements.

21. The lighting device of claim 18, wherein the one or more relief elements are one or more cutouts.
